(19) United States
(12) Patent Application Publication
(10) Pub. No.: US 2026/0240001 A1
(43) Pub. Date: Aug. 13, 2026

(54) COPPER FILM

(71) Applicants: OKUNO CHEMICAL INDUSTRIES CO., LTD., Osaka-shi, Osaka (JP); NICHIDEN SEIMITSU KOGYO CO., LTD., Ogaki-shi, Gifu (JP)

(72) Inventors: Ryota NAKA, Osaka-shi Osaka (JP); Junji YOSHIKAWA, Osaka-shi Osaka (JP); Takao ISHIHARA, Ogaki-shi Gifu (JP); Kozo OONO, Ogaki-shi Gifu (JP)

(73) Assignees: OKUNO CHEMICAL INDUSTRIES CO., LTD., Osaka-shi, Osaka (JP); NICHIDEN SEIMITSU KOGYO CO., LTD., Ogaki-shi, Gifu (JP)

(21) Appl. No.: 19/149,318

(22) PCT Filed: Jan. 18, 2024
(86) PCT No.: PCT/JP2024/001202

§ 371 Date: Jul. 18, 2025

(30) Foreign Application Priority Data
Jan. 19, 2023 (JP) 2023-006517

(51) Int. Cl. H10W 70/40; C25D 3/38; C25D 5/18; H10W 70/04

(52) U.S. Cl. CPC H10W 70/457; C25D 3/38; C25D 5/18; H10W 70/041

(57) ABSTRACT

The present invention aims to provide a novel copper coating. A copper coating, which is formed on a metal lead frame, the copper coating comprising a particle aggregate coating having a specific surface area of 1.3×10⁻³ m²/g to 2.2×10⁻³ m²/g, wherein the particle aggregate coating comprises particle aggregates each having a size of 15 μm or less.

### TECHNICAL FIELD

The present invention relates to a copper coating.

### BACKGROUND ART

In a semiconductor device, a semiconductor device is mounted on a lead frame, and the semiconductor device and the lead frame are electrically bonded by bonding wire. The mounted semiconductor device and the lead frame are then fixed in place with molding resin.

In recent years, there has been a demand to reduce heat generation caused by increased efficiency of semiconductor devices and to improve adhesion of molding resin for reduction in size of semiconductor device components.

In bonding between a semiconductor device and a lead frame, a method has been reported in which a coating having a higher arithmetic mean height (Sa) is formed on the lead frame itself and on its surface to improve adhesion between the lead frame and molding resin.

For example, Patent Literature 1 discloses a lead frame including a precious metal plating layer formed on a surface of a base metal via an undercoat plating layer. In the lead frame, the undercoat layer includes a smooth Ni plating layer and a roughened Ni plating layer, wherein the smooth Ni plating layer is plated on the base metal using a direct current or pulsed current having no polarity-reversing component, and the roughened Ni plating layer is plated on the smooth Ni plating layer using an electric current including a polarity-reversing pulse.

In this technique, the smooth Ni plating layer and the roughened Ni plating layer need to be selectively formed on the lead frame, because bonding wire is adhered to a smooth surface. The surface roughness (Ra) of the roughened Ni plating thus obtained is 0.1 to 0.8 μm, and the resin adhesion strength at that time is 22 to 25 MPa.

For example, Patent Literature 2 discloses a plating solution containing 200 g/L of copper sulfate pentahydrate, 25 g/L of sulfuric acid, 400 ppm of hydrochloric acid, 13.75 wt % of an inhibitor, and 7.5 wt % of an accelerator. According to the disclosure, this plating solution forms a roughened surface with excellent adhesion to molding resin in a simple process.

### CITATION LIST

### Patent Literature

PTL 1: JP2007-009334A
PTL 2: JP2022-127982A

### SUMMARY OF INVENTION

### Technical Problem

The present invention aims to provide a novel copper coating.

### Solution to Problem

As a result of extensive studies, the present inventors have developed a copper coating, which is formed on a lead frame made of a copper alloy. The copper coating provides excellent adhesion between the lead frame and molding resin, because the copper coating has a certain specific surface area.

Specifically, the present invention encompasses the following copper coating.

### Item 1.

A copper coating, which is formed on a metal lead frame,
the copper coating comprising a particle aggregate coating having a specific surface area of 1.3×10⁻³ m²/g to 2.2×10⁻³ m²/g,
wherein the particle aggregate coating comprises particle aggregates each having a size of 15 μm or less.

### Item 2.

The copper coating according to Item 1 having an arithmetic mean height (Sa) of 1.3 μm to 3.0 μm, as measured with a laser microscope.

The copper coating of the present invention is a copper coating formed on metal portions of a lead frame and a circuit board of a semiconductor device, and the copper coating improves adhesion between molding resin and bonding wire.

### Advantageous Effects of Invention

The present invention can provide a novel copper coating.

### BRIEF DESCRIPTION OF DRAWINGS

FIG. 1 shows a schematic diagram of the structure of a lead frame subjected to roughening plating.

FIG. 2 shows a view of an adhesion strength test method.

FIG. 3 shows electron microscope images including (A) a copper coating of the present invention (Example) and (B) a copper coating of a conventional technique (Comparative Example). The copper coating of the present invention is made of a particle aggregate coating having a specific surface area of 1.3×10⁻³ m²/g to 2.2×10⁻³ m²/g.

FIG. 4 shows electron microscope images of the copper coating of the present invention (Example). The copper coating of the present invention is made of a particle aggregate coating having a specific surface area of 1.3×10⁻³ m²/g to 2.2×10⁻³ m²/g, and the particle aggregate coating includes particles (nodular particles) having a size of 15 μm or less.

### DESCRIPTION OF EMBODIMENTS

The present invention will be described in detail below.

The embodiments representing the present invention are described for better understanding of the gist of the invention, and are not intended to limit the contents of the invention unless otherwise specified.

Herein, the terms “include” and “contain” and variations thereof express concepts that encompass all of “comprise,” “consist essentially of,” and “consist of.”

Herein, when a numerical range is expressed as “A to B,” the expression means “A or more and B or less.”

### 1. Copper Coating

The copper coating is made of a particle aggregate coating having a specific surface area of 1.3×10⁻³ m²/g to 2.2×10⁻³ m²/g, and the particle aggregate coating includes particle aggregates having an average particle size of 15 μm or less.

The copper coating of the present invention is a copper coating, which is formed on a metal lead frame.

The copper coating of the present invention is made of a particle aggregate coating having a specific surface area of 1.3×10⁻³ m²/g to 2.2×10⁻³ m²/g.

The particle aggregate coating includes particle aggregates (nodular particles) each having a size of 15 μm or less.

Each particle aggregate having a size of 15 μm or less includes particles having an average particle size of 2 μm to 3 μm that are aggregated to form a particle aggregate.

Preferably, the copper coating of the present invention has an arithmetic mean height (Sa) of 1.3 μm to 3.0 μm (as measured with a laser microscope).

In the copper coating of the present invention, the metal forming the lead frame is preferably an alloy such as a copper alloy or an iron-nickel alloy, more preferably a copper alloy (a lead frame made of a copper alloy).

Conventional plating methods have problems such as separation of a metal plating layer on a plated roughened surface from molding resin due to heat history, and low bonding strength due to poor adhesion of bonding wire to a roughened surface of a metal coating formed.

In view of these problems, the present invention provides a copper coating that forms a roughened surface with excellent adhesion between molding resin and bonding wire in a simple process. The copper coating of the present invention exhibits suitable wire bonding strength.

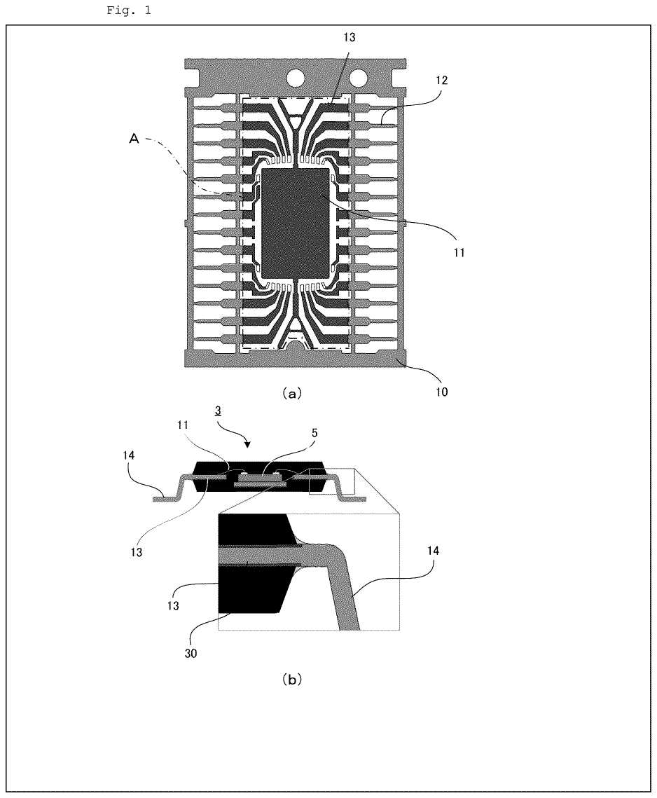

In the present invention, when forming a copper coating on a lead frame using a periodic reverse (PR) pulse electrolysis method, a first current is applied for a first period using the lead frame as an electrode, and after forming an extremely thin copper coating on a surface of the lead frame, a second current is applied for a second period in which the total applied current is adjusted so as to not invade lead frame A (a region to be molded, indicated by “A” in FIG. 1(a)).

This is repeated a predetermined number of times, whereby a copper metal coating having a certain specific surface area is formed on the lead frame.

The electrolytic process of forming the copper coating of the present invention is different from that of the conventional technique (JP2022-127982A) in that the first current is applied for the first period to form a coating and that no step of applying a third current for a third period is included, i.e., the process is completed in a very short time.

### Application Example 1

Preferably, the copper coating of the present invention is produced using copper plating solution containing a copper salt, an acid component, a halide ion, a sulfur-containing organic compound (accelerator), and a non-ionic polyether polymer surfactant (inhibitor).

### Application Example 2

In copper plating, the non-ionic polyether polymer surfactant (inhibitor) is preferably polyethylene glycol (PEG), and the sulfur-containing organic compound (accelerator) is preferably bis(3-sulfopropyl) disulfide (SPS).

### Application Example 3

The copper coating of the present invention is produced using a PR pulse electrolysis method.

The PR pulse electrolysis method is a plating method of performing copper plating on a lead frame. Using the plating solution (copper plating solution), the method includes the following:
(1) a first film forming process in which a first current is applied for a first period using the lead frame as an electrode to form a coating on a surface of the lead frame;
(2) a dissolution process, subsequent to the first film forming process, in which a second current is applied for a second period using the lead frame as an electrode to dissolve the coating; and
(3) repetition of the above processes a predetermined number of times, thus plating the lead frame.

With this plating method, (1) a copper coating is formed on the surface of the lead frame, (2) the copper coating formed is dissolved, and (3) a new copper coating is formed on a portion where the copper coating was dissolved. These processes are repeated, and thus a roughened copper coating (copper plating) can be formed on the surface of the lead frame.

The metal forming the lead frame is preferably an alloy such as a copper alloy or an iron-nickel alloy, more preferably a copper alloy (a lead frame made of a copper alloy).

With this plating method, copper(I) ions can be effectively generated in a convection surface layer of a workpiece, providing excellent adhesion between the lead frame and the copper coating formed.

When the lead frame (metal material) is plated using the above plating method (electrolysis conditions), the surface of the lead frame is roughened. When the lead frame is bonded (molded) with molding resin, such a surface can form a roughened surface with excellent adhesion between the lead frame and the molding.

The thus-formed roughened surface has a higher adhesion strength to bonding wire than copper coatings formed by conventional methods.

In the PR pulse electrolytic method, when the lead frame is copper plated using the plating solution (preferably a plating solution containing PEG as an inhibitor and SPS as an accelerator), large nodular particles are formed densely and uniformly on the surface of the lead frame.

In this manner, the surface of the lead frame is roughened. When the lead frame is bonded with molding resin, a roughened surface (copper coating) with excellent adhesion between the lead frame and the molding resin can be formed. The thus-formed roughened surface provides excellent adhesion between the lead frame and bonding wire.

### Application Example 4

The copper coating formed on the surface of the lead frame is a coating made of particle aggregates (nodular particles). The copper coating is made of a particle aggregate coating having a specific surface area of 1.3×10⁻³ m²/g to 2.2×10⁻³ m²/g, as determined by the BET method (Brunauer, Emmet and Teller's equation (BET equation)).

The particle aggregate coating includes particle aggregates each having a size of 15 μm or less.

Each particle aggregate having a size of 15 μm or less includes particles having an average particle size of 2 μm to 3 μm that are aggregated to form a particle aggregate.

The “nodular particle” of the present invention represents a particle with a so-called “undercut shape,” which is a balloon- or bubble-shape in which the cross-sectional area of at least a portion of the upper part is larger than the cross-sectional area of the bottom part. The “nodular particle” also includes a grown particle consisting of several nodular particles continuous with each other (a particle aggregate coating).

The copper coating has an arithmetic mean height (Sa) of preferably 1.3 μm to 3.0 μm, more preferably 1.5 μm to 3.0 μm, as measured with a laser microscope.

Large nodular particles are densely and uniformly formed on the surface of the lead frame. When the surface of the lead frame is roughened and the lead frame is bonded (molded) with molding resin, a roughened surface (copper coating) with excellent adhesion between the lead frame and molding resin can be formed. The thus-formed roughened surface provides excellent adhesion between the lead frame and bonding wire.

### Application Example 5

Preferably, the copper coating is formed by a method such as a sintering method of sintering a metal and a resin, or a method of making a metal or resin material conductive and then electrolytically plating the metal or resin material.

Conventionally, when a porous metal is produced using the sintering method, a metal-resin-containing layer containing a metal and a resin having a lower melting point than the metal is formed on a substrate, the metal-resin-containing layer is heated to sinter the metal, and the resin is removed from the metal-resin-containing layer to obtain a porous metal body (e.g., JP2017/221500A1). However, this technique has problems such that the shape of the resulting metal coating is limited and that special equipment is required.

The copper coating of the present invention is a copper coating, which is formed on metal portions of a lead frame and a circuit board of a semiconductor device, and the copper coating improves adhesion between molding resin and bonding wire.

### 2. Production of Copper Coating

### (1) Copper Plating Solution for Forming Copper Coating (Copper Sulfate Plating Solution)

Preferably, the copper plating solution contains a copper salt (copper(II) ion), an acid component, a halide ion, a sulfur-containing organic compound, and a non-ionic polyether polymer surfactant.

The copper(II) ion concentration in the plating solution is preferably adjusted within a range of 50 g/L to 270 g/L. Preferably, the copper salt (copper(II) ion) is copper sulfate, which is used at a concentration of 200 g/L to 250 g/L as copper sulfate.

The acid component concentration in the copper plating solution is not limited as long as electrical conductivity is obtained, but it is preferably adjusted within a range of 0 g/L to 100 g/L, more preferably 0 g/L to 50 g/L. Preferably, the acid component is sulfuric acid.

Preferably, the halide ion concentration in the copper plating solution is adjusted within a range of 10 mg/L to 500 mg/L, more preferably 300 mg/L to 400 mg/L (300 ppm to 400 ppm). Preferably, the halide ion is a chloride ion.

Preferably, the sulfur-containing organic compound concentration in the copper plating solution is adjusted within a range of 0.5 mg/L to 50 mg/L, more preferably 1 mg/L to 5 mg/L.

Preferably, the sulfur-containing organic compound (accelerator) is bis(3-sulfopropyl) disulfide (SPS). Preferably, the sulfur-containing organic compound (accelerator) is a sulfur compound such as 3-mercaptopropanesulfonic acid or its sodium salt, bis(3-sulfopropyl) disulfide or its disodium salt, or N,N-dimethyldithiocarbamic acid (3-sulfopropyl) ester or its sodium salt.

These sulfur-containing organic compounds may be used alone or in a combination (blend) of two or more thereof.

The non-ionic polyether polymer surfactant concentration in the copper plating solution is adjusted within a range of preferably 0.01 g/L to 10 g/L (more preferably 150 mg/L to 300 mg/L).

Preferably, the non-ionic polyether polymer surfactant (inhibitor) is polyethylene glycol (PEG). The average molecular weight of the PEG used is preferably about 600 to 6,000, more preferably about 1,000 to 4,000. Preferably, the non-ionic polyether polymer surfactant (inhibitor) is a polyether compound such as polypropylene glycol, polyethylene oxide, or polyoxyalkylene glycol.

These non-ionic polyether polymer surfactants may be used alone or in a combination (blend) or two or more thereof.

### (2) Copper Plating Method of Forming Copper Coating

### Pulse Conditions

In the copper plating method based on the PR pulse electrolysis method, electrolytic copper plating is performed on a workpiece used as a cathode by applying a PR pulse current using the acidic copper plating solution.

Regarding PR pulse current application conditions using the copper plating solution, the current density of the positive electrolysis for depositing a copper-plated coating is preferably about 0.5 ASD (A/dm²) to 200 ASD (A/dm²), more preferably about 75 ASD to 100 ASD, still more preferably about 40 ASD to 60 ASD.

Regarding PR pulse current application conditions using the copper plating solution, the current density of the negative electrolysis for dissolving the copper-plated is preferably 0.2 ASD to 100 ASD, more preferably about 20 ASD to 50 ASD, still more preferably 20 ASD to 35 ASD.

The positive current application time (current flow time for depositing copper on a workpiece, positive electrolysis time) is preferably about 10 msec to 1,000 msec, more preferably about 50 msec to 300 msec, and more preferably 85 msec to 120 msec.

The negative current application time (current flow time for dissolving copper from the workpiece, negative electrolysis time) is preferably 0.1 msec to 100 msec, more preferably 4 msec to 25 msec (still more preferably 10 msec to 15 msec).

Preferably, the copper plating method based on the PR pulse electrolysis method is performed under PR pulse electrolysis conditions in which the positive current application time is 50 msec to 300 msec and the ratio of application time of positive current to negative current (positive current application time/negative current application time) is 7 or more and less than 30.

In comparison, in the case of a conventional technique (JP2022-127982A), a film-rupture current that dissolves a workpiece (cathode) is used as a first current, and a current that deposits copper on the workpiece is used as a second current.

Further, after the first current and the second current are applied for a first period and a second period, respectively, the potential difference between the anode (the positive electrode) and the cathode (the negative electrode) is held at 0 [V] for 50 [ms] (third period), whereby a coating is formed.

### Plating

### (1) Pre-Treatment

Pre-treatment is performed on the lead frame. The pre-treatment includes degreasing and pickling. Contaminants, such as oil and metal powder, adhering to the surface of the lead frame made of a copper alloy are removed to make the surface clean and suitable for plating.

Preferably, the pre-treatment involves soft etching, degassing, and pickling.

### (2) Formation of Copper Coating

Using the lead frame as the cathode, and an insoluble anode (iridium (Ir) coating) as the anode, a current (first current) having a current density within a range of preferably about 0.5 ASD to 200 ASD, more preferably about 75 ASD to 100 ASD, is applied for preferably about 10 msec to 1,000 msec, more preferably about 50 msec to 300 msec (first period).

### (3) Destruction of Copper Coating (Copper(I) Ion Generation Period)

Next, a current (second current) having a current density of preferably about 0.2 ASD to 100 ASD, more preferably about 30 ASD to 50 ASD, is applied preferably for about 0.1 msec to 100 msec, more preferably about 4 msec to 25 msec (second period).

### (4) Repetition of Copper Coating Formation and Dissolution of Copper Coating Formed

Processes (2) and (3) described above are repeated a predetermined number of times such that the copper coating (copper plating) formed on the lead frame is made of a particle aggregate coating having a specific surface area of 1.3×10⁻³ m²/g to 2.2×10⁻³ m²/g. The particles (nodular particles) forming the particle aggregate coating have an average particle size of 15 μm or less.

### Structure of Lead Frame (FIG. 1)

With reference to FIG. 1, the structure of a lead frame 10 that is a metal material subjected to roughening plating is described. FIG. 1 shows a schematic structure of the lead frame 10 subjected to roughening plating. FIG. 1(a) is a plan view. FIG. 1(b) is a cross-sectional view of an integrated circuit 3 in which the lead frame 10 is packaged in a molding resin 30.

The lead frame 10 is made of a copper alloy, and includes a die pad 11 that supports and fixes a semiconductor device 5, an inner lead 13 to which a wire (a bonding wire 12) for the semiconductor device 5 is connected, and an outer lead 14 that bridges the external wiring.

As shown in FIG. 1(b), the lead frame 10 is molded with the molding resin 30 and is thus provided as the integrated circuit 3 such as an IC. To completely remove resin burrs generated during resin molding, roughening plating is performed only on a region to be molded (the region indicated by “A” in FIG. 1(a)) of the lead frame 10, and no roughening plating is performed on the other regions not to be molded.

### EXAMPLES

The present invention is specifically described below with reference to an example.

The specific example below is not intended to limit the present invention.

### 1. ROUGHENING PLATING OF LEAD FRAME

TABLE 1
Table 1: Copper Plating Conditions

| | | |
|---|---|---|
| Copper sulfate | Main | Copper sulfate 250 g/L, |
| plating solution | components | sulfuric acid 50 g/L, |
| | | chloride ion 400 ppm |
| Liquid | Additives | PEG (high molecular weight range) |
| composition | | 250 mg/L |
| | | Sulfur compound 3 mg/L |
| PR pulse | Current | Positive: 40 to 60 ASD |
| | density | Negative: 20 to 35 ASD |
| Electrolysis | Application | Positive: 85 to 120 msec |
| | time | Negative: 10 to 15 msec |
| | Temperature | 25° C. |

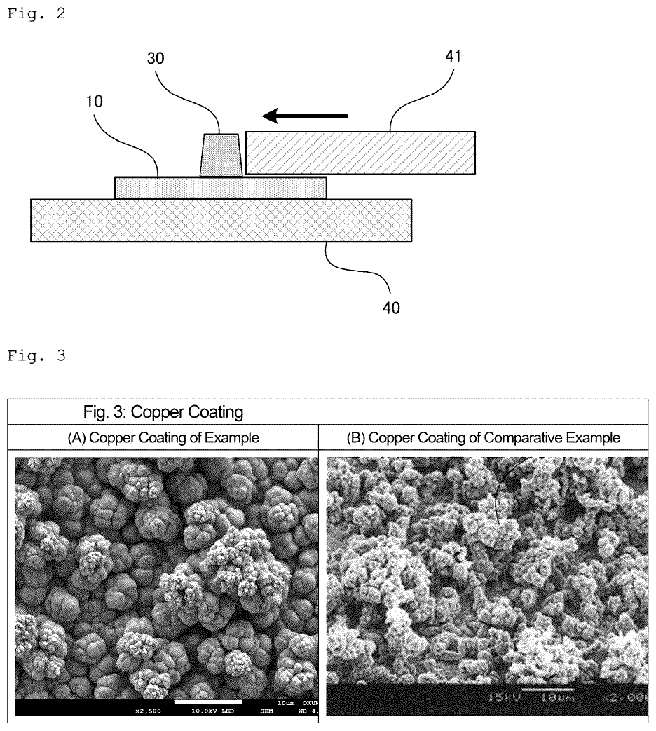

### Adhesion Strength Test (FIG. 2)

An adhesion strength test method is described with reference to FIG. 2.
(1) A test frame 10 on which roughening plating was performed is cut into individual 1 cm square test pieces (the lead frame (metal materials) 10).
(2) The molding resin 30 is molded, with the roughened plated surface of a test piece facing up.
(Conditions) time: 90 seconds+α; temperature: 180° C.
(3) The resulting product is dried.
(Conditions) time: 8 hours; temperature: 175° C.
(4) An accelerated environmental test is performed on the product placed in a temperature and humidity chamber.
(Conditions) time: 168 hours; temperature: 88° C.; humidity: 85% (accelerated environmental test, JEDEC standard, MSL1 compliant)
(5) A reflow heating test is performed.
(Conditions) Number of times: 10 times; time: 1 min.→1 min, temperature: 180° C. to 190° C.→230° C. to 240° C. (accelerated environmental test, JEDEC standard, MSL1 compliant)
(6) A shear strength test is performed.

In the shear strength test, as shown in FIG. 2, the lead frame (metal material) 10 as a test piece is placed on a base 40, and a side surface of the molding resin 30 molded thereon is pressed by a tool 41 to apply a force (indicated by an arrow in FIG. 2). The pressure at which the molding resin 30 is separated from the test piece is regarded as the adhesion strength.

### Measurement of Specific Surface Area (Kr Gas Adsorption Method)

Sample: copper coatings
Measurement and analysis device: 3Flex available from Micromeritics Instrument Corporation (specific surface area measurement device)
   Smart VacPrep (pre-treatment device) available from Micromeritics Instrument Corporation
   Measurement and analysis method: A copper coating is placed in a large special cell, degassed in vacuum at 110° C. for 6 hours using a pre-treatment device, and then subjected to specific surface area measurement using Kr gas.

The molecular cross-sectional area of Kr gas is set to 0.202 nm².

Measurement analysis results: Measurements are performed up to P/Po=about 0.3.

### 2. COPPER COATING EVALUATION

### Copper Coating of Comparative Example (FIG. 3(B))

FIG. 3(B) shows a 2,500-fold enlarged view of a surface of a lead frame plated using a method disclosed in a conventional technique (JP2022-127982A) (the copper coating of the Comparative Example).

In the copper coating of the Comparative Example, particles of irregular size were randomly formed on the surface of the lead frame.

The copper coating of the Comparative Example had an arithmetic mean height (Sa) of 2.7 μm to 3.0 μm.

The copper coating of the Comparative Example had a wire bonding strength of 50 mN to 60 mN.

The copper coating of the Comparative Example had a resin adhesion strength of 25 MPa to 30 MPa.

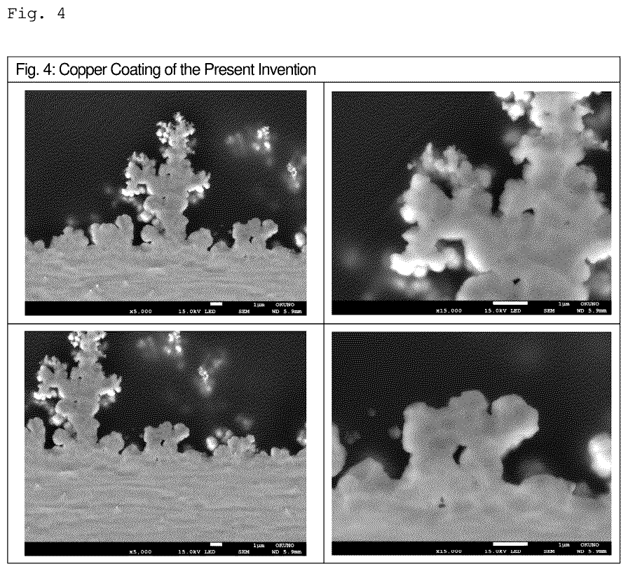

### Copper Coating (FIG. 3(A) and FIG. 4) of Example

FIG. 3(A) shows an electron microscopic image of the surface morphology of the lead frame of the present invention on which roughening plating was performed (copper coating of Example). FIG. 3(A) is a 2,500-fold enlarged view of a surface of the lead frame plated using the plating solution by the roughening plating method (PR pulse electrolysis method).

The copper coating of the Example was a copper coating in which many nodular particles were formed densely and uniformly.

On the surface of the lead frame of the Example on which roughening plating (copper coating) was performed, there was formed a copper coating including nodular particle aggregates each having a size of about 5 μm to 10 μm. The copper coating of the Example was a copper coating (particle aggregate coating) in which the nodular particles included three-dimensional and finer nodular particles that were densely and regularly connected thereto.

The copper coating formed on the surface of the lead frame of the Example was made of a particle aggregate coating (nodular particles), and the specific surface area calculated using the Kr gas adsorption method (BET method) was 1.3×10⁻³ m²/g to 2.2×10⁻³ m²/g. The particles forming the particle aggregate coating had an average particle size of 15 μm or less.

The copper coating of the Example had an arithmetic mean height (Sa) of 2.0 μm to 2.8 μm.

The “nodular particle” of the Example represents a particle with a so-called “undercut shape,” which is a balloon- or bubble-shape in which the cross-sectional area of at least a portion of the upper part is larger than the cross-sectional area of the bottom part. The “nodular particle” also includes a grown particle consisting of several nodular particles continuous with each other.

The copper coating of the Example had a wire bonding strength of 70 mN to 80 mN.

The copper coating of the Example had a resin adhesion strength of 30 MPa to 37 MPa.

TABLE 2
Table 2: Method and Evaluation Results

| | | | Specific | | | Molding |
|---|---|---|---|---|---|---|
| | | Arithmetic | surface area | | Bonding | resin adhesion |
| | | Mean height | (BET method) | | strength | strength |
| | Method | (Sa) (μm) | (×10⁻³ m²/g) | | (mN) | (MPa) |
| Example | Method of | 2.6 | 2.2 | | 79 | 35.4 |
| | the present invention | | | | | |
| | Sintering method | 2.5 | 2.1 | | 74 | 34.2 |
| Comparative | Roughening | 2.8 | 1.6 | | 55 | 27.2 |
| Example | Cu plating | | | | | |
| | (Prior Patent 2) | | | | | |
| | Roughening | 1.1 | 1.3 | 1.2 | 66 | 24.3 |
| | Ni plating | | (Molding | (Smooth | | |
| | (conventional method) | | resin portion) | portion) | | |
| | Brown oxide | 0.5 | 1.1 | | 31 | 13.4 |
| | treatment | | | | | |

| | | | | |
|---|---|---|---|---|
| Untreated | 0.2 | 1 | 52 | 13.1 |

### 3. INDUSTRIAL APPLICABILITY

Use of the roughening plating method to which the present invention is applied enables production of a copper coating in which regularly shaped nodular particles are densely and regularly formed on the surface of the lead frame.

The copper coating of the present invention has a high specific surface area. Thus, the molding resin, when molded, enters between the nodular particles and then exhibits an anchoring effect.

When compared to the conventional technique, the copper coating of the present invention is strongly adhered to bonding wire during wire bonding because the nodular particle aggregate coating includes coating particles that are formed.

When compared to a copper coating formed by a conventional roughening plating method using particles having a shape such as a needle shape, a conical shape, or a pyramidal shape, the nodular particle aggregate coating defining the copper coating of the present invention can be filled with a large amount of molding resin, resulting in high adhesion strength of the molding resin to the plating layer.

The copper coating of the present invention also has a high adhesion strength to bonding wire.

### DESCRIPTION OF THE REFERENCE NUMERALS

3: integrated circuit
5: semiconductor device
10: lead frame
11: die pad
12: bonding wire
13: inner lead
14: outer lead
30: molding resin
40: base
41: tool

1-2. (canceled)

3. A copper coating, which is formed on a metal lead frame, the copper coating comprising a particle aggregate coating having a specific surface area more than 1.6×10⁻³ m²/g to 2.2×10⁻³ m²/g or less,
wherein the particle aggregate coating comprises particle aggregates each having a size of 15 μm or less.

4. The copper coating according to claim 3 having an arithmetic mean height (Sa) of 1.3 μm to 3.0 μm.

5. A method of producing a copper coating on a lead frame using a copper plating solution by a PR pulse electrolysis method, the copper coating comprising a particle aggregate coating having a specific surface area of 1.3×10⁻³ m²/g to 2.2×10⁻³ m²/g, the particle aggregate coating comprising particle aggregates each having a size of 15 μm or less, wherein
the copper plating solution contains a copper salt, an acid component, a halide ion, a sulfur-containing organic compound, and a non-ionic polyether polymer surfactant, and
the PR pulse electrolysis method uses the lead frame as a negative electrode or a cathode and comprises:
(1) a first film forming process in which a first current having a current density of 0.5 ASD to 200 ASD is applied using the lead frame as an electrode for a first period of 10 msec to 1,000 msec to form a coating on a surface of the lead frame using the plating solution;
(2) a dissolution process, subsequent to the first film forming process, in which a second current having a current density of 0.2 ASD to 100 ASD is applied using the lead frame as an electrode for a second period of 0.1 msec to 100 msec to dissolve the coating; and
(3) repetition of the above processes a predetermined number of times to perform copper plating on the lead frame.

6. The method according to claim 5,
wherein
the copper plating solution has
a copper(II) ion concentration derived from the copper salt of 50 g/L to 270 g/L,
an acid component concentration of 0 g/L to 100 g/L,
a halide ion concentration of 10 mg/L to 500 mg/L,
a sulfur-containing organic compound concentration of 0.5 mg/L to 50 mg/L, and
a non-ionic polyether polymer surfactant concentration of 0.01 g/L to 10 g/L.

7. The method according to claim 5,
wherein in the copper plating solution,
the copper salt is copper sulfate,
the acid component is sulfuric acid,
the halide ion is a chloride ion,
the sulfur-containing organic compound is at least one component selected from the group consisting of bis(3-sulfopropyl) disulfide (SPS), 3-mercaptopropanesulfonic acid and its sodium salt, bis(3-sulfopropyl) disulfide and its disodium salt, N,N-dimethyldithiocarbamic acid (3-sulfopropyl) ester and its sodium salt, and
the non-ionic polyether polymer surfactant is at least one component selected from the group consisting of polyethylene glycol (PEG), polypropylene glycol, polyethylene oxide, and polyoxyalkylene glycol.

8. The method according to claim 5,
wherein in the PR pulse electrolysis method,
the lead frame is used as a negative electrode or a cathode,
the first film forming process (1) includes application of the first current having a current density of 40 ASD to 200 ASD, and
the dissolution process (2) includes application of the second current having a current density of 0.2 ASD to 35 ASD.

9. Wire bonding comprising:
forming, on a lead frame, the copper coating as defined in claim 3; and
connecting wiring between the lead frame and a semiconductor device via a bonding wire.

10. Wire bonding comprising:
forming, on a lead frame, a copper coating that is produced by the method as defined in claim 5; and
connecting wiring between the lead frame and a semiconductor device via a bonding wire.

11. An integrated circuit, a circuit board, or a semiconductor device, comprising a lead frame having the copper coating as defined in claim 3 formed thereon.

12. An integrated circuit, a circuit board, or a semiconductor device, comprising a lead frame having a copper coating that is produced by the method as defined in claim 5 formed thereon.
